(19) United States
(12) Patent Application Publication
(10) Pub. No.: US 2014/0196778 A1
(43) Pub. Date: Jul. 17, 2014

(54) LIGHT ABSORBING MATERIAL AND SOLAR CELL INCLUDING THE SAME

(71) Applicant: Samsung Electronics Co., Ltd., Suwon-Si (KR)

(72) Inventor: Jin Wook LEE, Suwon-si (KR)

(73) Assignee: SAMSUNG ELECTRONICS CO., LTD., Suwon-Si (KR)

(21) Appl. No.: 14/152,325

(22) Filed: Jan. 10, 2014

(30) Foreign Application Priority Data
Jan. 14, 2013 (KR) 10-2013-0004091

(51) Int. Cl. H01L 31/0272; H01L 31/0352

(52) U.S. Cl. CPC H01L 31/0272; H01L 31/035218
USPC 136/255; 136/264; 423/508

(57) ABSTRACT

A light absorbing material may have an energy bandgap of greater than or equal to about 0.8 eV and an absorption coefficient of greater than about 2.1×10⁵ cm⁻¹ at about 0.8 eV.

### CROSS REFERENCE TO RELATED APPLICATION

This application claims priority to and the benefit of Korean Patent Application No. 10-2013-0004091 filed in the Korean Intellectual Property Office on Jan. 14, 2013, the entire contents of which are incorporated herein by reference.

### BACKGROUND

1. Field

Example embodiments relate to a light absorbing material and a solar cell including the same.

2. Description of the Related Art

A solar cell is a photoelectric conversion device that transforms solar energy into electrical energy, and has attracted attention as an infinite but pollution-free next generation energy source.

A solar cell produces electrical energy by transferring electrons and holes to n-type and p-type semiconductors, respectively, and then collecting electrons and holes in each electrode when an electron-hole pair (EHP) is produced by solar energy absorbed in a photoactive layer inside the semiconductors.

In order to produce more electrical energy of a solar cell, a solar cell is required to efficiently absorb incident light and to collect charges produced by the absorbed light.

### SUMMARY

Example embodiments provide a light absorbing material that may increase light absorption and realize a relatively thin solar cell.

Example embodiments provide a solar cell including the light absorbing material.

According to example embodiments, a light absorbing material has an energy bandgap of greater than or equal to about 0.8 eV and an absorption coefficient of greater than about 2.1×10⁵ cm⁻¹ at about 0.8 eV.

The light absorbing material may be at least one material selected from RhSb₃, CeN, SnTe, LaSb, CoSb₃, ZnSnSb₂, CsBi₂, Cu₃SbSe₄, MnSi, Cu₂SnSe₃, Cu₃SbS₄, SmSb, CoO, Li₃P, TISe, PrSb, and PtS.

The light absorbing material may be a semiconductor crystal having a particle radius of about 2 nm to about 500 nm, and the energy bandgap of the light absorbing material may vary depending on the particle radius.

According to example embodiments, a solar cell includes a first electrode and a second electrode facing each other, and at least one photoactive layer between the first electrode and the second electrode, the at least one photoactive layer including a light absorbing material having an energy bandgap of greater than or equal to about 0.8 eV and an absorption coefficient of greater than about 2.1×10⁵ cm⁻¹ at about 0.8 eV.

The light absorbing material may be at least one material selected from RhSb₃, CeN, SnTe, LaSb, CoSb₃, ZnSnSb₂, CsBi₂, Cu₃SbSe₄, MnSi, Cu₂SnSe₃, Cu₃SbS₄, SmSb, CoO, Li₃P, TISe, PrSb, and PtS. The light absorbing material may be a semiconductor crystal having a particle radius of about 2 nm to about 500 nm.

The solar cell may further include an auxiliary layer between at least one of the first electrode and the at least one photoactive layer, and the second electrode and the at least one photoactive layer.

The at least one photoactive layer may have a tandem structure including at least two stacked photoactive layers. The at least one photoactive layer may include a first photoactive layer and a second photoactive layer including light absorbing materials having different particle radii from each other. The first photoactive layer may include a light absorbing material having a first particle radius, the second photoactive layer may include the light absorbing material having a second particle radius, the second particle radius larger than the first particle radius, and the first photoactive layer absorbs light having a shorter wavelength range than the second photoactive layer.

The solar cell may further include an interconnecting layer between the first photoactive layer and the second photoactive layer.

The at least one photoactive layer includes a first photoactive layer, a second photoactive layer, and a third photoactive layer may include light absorbing materials having different particle radii from each other. The first photoactive layer may include a light absorbing material having a particle radius showing an energy bandgap of about 2.1 eV to about 2.5 eV, the second photoactive layer may include a light absorbing material having a particle radius showing an energy bandgap of about 1.2 eV to about 1.6 eV, and the third photoactive layer may include a light absorbing material having a particle radius showing an energy bandgap of about 0.8 eV to about 1.0 eV.

The first photoactive layer may include a light absorbing material having a first particle radius, the second photoactive layer may include a light absorbing material having a second particle radius, the second particle radius larger than the first particle radius, the third photoactive layer may include a light absorbing material having a third particle radius, the third particle radius larger than the second particle radius, and the first photoactive layer, the second photoactive layer, and the third photoactive layer absorb light having a first wavelength range, a second wavelength range longer than the first wavelength range, and a third wavelength range longer than the first and second wavelength ranges, respectively.

The first particle radius may range from about 2 nm to about 20 nm, the second particle radius may range from about 3 nm to about 50 nm, and the third particle radius may range from about 6 nm to about 300 nm. The first wavelength range may be less than or equal to about 590 nm, the second wavelength range may be from about 591 nm to about 1033 nm, and the third wavelength range may be from about 1034 nm to about 2066 nm. The solar cell may further include at least one interconnecting layer between the first photoactive layer and the second photoactive layer, and between the second photoactive layer and the third photoactive layer.

According to example embodiments, a solar cell includes a first electrode and a second electrode facing each other, and at least one photoactive layer between the first electrode and the second electrode, the at least one photoactive layer including a light absorbing material having a particle radius of about 2 nm to 500 nm, wherein the light absorbing material is at least one material selected from RhSb₃, CeN, SnTe, LaSb, CoSb₃, ZnSnSb₂, CsBi₂, Cu₃SbSe₄, MnSi, Cu₂SnSe₃, Cu₃SbS₄, SmSb, CoO, Li₃P, TISe, PrSb, and PtS.

The at least one photoactive layer may include a first photoactive layer, a second photoactive layer, and a third photoactive layer including light absorbing materials having different particle radii from each other. The first photoactive layer may include a light absorbing material having a particle radius of about 2 nm to about 20 nm, the second photoactive layer may include a light absorbing material having a particle radius of about 3 nm to about 50 nm, and the third photoactive layer may include a light absorbing material having a particle radius of about 6 nm to about 300 nm.

### BRIEF DESCRIPTION OF THE DRAWINGS

These and/or other aspects will become apparent and more readily appreciated from the following description of the embodiments, taken in conjunction with the accompanying drawings in which:

FIG. 1 is a cross-sectional view showing a solar cell according to example embodiments,

FIG. 2 is a cross-sectional view showing a solar cell according to example embodiments,

FIG. 3 is a cross-sectional view showing a solar cell according to example embodiments, and

FIG. 4 is a transmission electron microscope (TEM) photograph showing the SnTe nanocrystal according to a synthesis example.

### DETAILED DESCRIPTION

Example embodiments will hereinafter be described in detail referring to the following accompanied drawings, and can be more easily performed by those who have common knowledge in the related art. However, these embodiments are only examples, and the inventive concepts are not limited thereto.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

It should be understood that, although the terms first, second, third, etc. may be used herein to describe various elements, components, regions, layers and/or sections, these elements, components, regions, layers, and/or sections should not be limited by these terms. These terms are only used to distinguish one element, component, region, layer, or section from another region, layer, or section. Thus, a first element, component, region, layer, or section discussed below could be termed a second element, component, region, layer, or section without departing from the teachings of example embodiments.

Spatially relative terms (e.g., “beneath,” “below,” “lower,” “above,” “upper,” and the like) may be used herein for ease of description to describe one element or feature's relationship to another element(s) or feature(s) as illustrated in the figures. It should be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other orientations) and the spatially relative descriptors used herein interpreted accordingly.

The terminology used herein is for the purpose of describing various embodiments only and is not intended to be limiting of example embodiments. As used herein, the singular forms “a,” “an,” and “the” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

Hereinafter, a light absorbing material according to example embodiments is described.

The light absorbing material according to example embodiments is a material having an energy bandgap of greater than or equal to about 0.8 eV and an absorption coefficient of greater than about 2.1×10⁵ cm⁻¹ at about 0.8 eV.

The light absorbing material may be, for example, a binary compound or a ternary compound synthesized by combining elements of Groups I to VI, for example, a compound of Groups IA and VA, a compound of Groups VIIB and IVA, a compound of Groups VIII and VA, a compound of Groups VIII and VIA, a compound of Groups IIIA and VIA, a compound of Groups IVB and VIA, a lanthanide compound, or a combination thereof.

The light absorbing material may be a semiconductor nanocrystal having a particle radius ranging from several nanometers to hundreds of nanometers, for example, a quantum dot. The light absorbing material may have an energy bandgap that is adjusted depending on a material and its size. For example, if the light absorbing material has a smaller particle radius, the light absorbing material has a larger energy bandgap. If the light absorbing material has a larger particle radius, the light absorbing material has a smaller energy bandgap.

The light absorbing material may be, for example, a bulk semiconductor crystal having an energy bandgap of less than about 0.8 eV, and having a particle radius ranging from about 2 nm to about 500 nm, while realizing an energy bandgap of greater than or equal to about 0.8 eV.

The light absorbing material may include at least one semiconductor nanocrystal selected from, for example, RhSb₃, CeN, SnTe, LaSb, CoSb₃, ZnSnSb₂, CsBi₂, Cu₃SbSe₄, MnSi, Cu₂SnSe₃, Cu₃SbS₄, SmSb, CoO, Li₃P, TISe, PrSb, and PtS.

The light absorbing material may have a particle radius of, for example, about 2 nm to about 500 nm, and may be selected so that desired energy bandgaps of greater than or equal to about 0.8 eV and an absorption wavelength range may be obtained within the above range of the particle radius.

Table 1 shows the energy bandgap (Eg) and absorption coefficient of the bulk semiconductor crystal, as well as an average particle radius thereof corresponding to a predetermined or given energy bandgap.

TABLE 1

| | | | | Absorp- | Average particle radius | | |
|---|---|---|---|---|---|---|---|
| | | | | tion | (R, nm) | | |
| | Eg | | | coeffi- | @0.8 | @1.4 | @2.3 |
| | (eV) | mₕ | mₑ | cient | eV | eV | eV |
| RhSb₃ | 0.80 | 0.10 | 0.01 | 857449.6 | 255.00 | 15.26 | 9.65 |
| Li₃P | 0.72 | 0.08 | 0.09 | 576982.9 | 16.39 | 5.62 | 3.69 |
| MnSi | 0.80 | 0.07 | 0.13 | 564831.9 | 18.00 | 5.82 | 3.68 |
| Cu₃SbS₄ | 0.74 | 0.03 | 0.15 | 479351.6 | 24.66 | 7.44 | 4.84 |
| ZnSnSb₂ | 0.40 | 0.04 | 0.02 | 459458.5 | 13.26 | 8.39 | 6.09 |
| CsBi₂ | 0.55 | 0.28 | 0.03 | 451441.9 | 12.19 | 6.61 | 4.61 |
| Cu₂SnSe₃ | 0.66 | 0.08 | 0.11 | 421915.0 | 11.80 | 5.13 | 3.45 |
| TlSe | 0.57 | 0.54 | 0.10 | 388266.3 | 6.92 | 3.64 | 2.52 |
| PtS | 0.80 | 0.23 | 0.12 | 335633.7 | 13.00 | 4.42 | 2.79 |
| CoSb₃ | 0.63 | 0.03 | 0.28 | 318297.9 | 14.56 | 6.84 | 4.65 |
| SmSb | 0.59 | 0.36 | 0.05 | 310753.7 | 10.43 | 5.31 | 3.65 |
| PrSb | 0.66 | 0.08 | 0.14 | 304400.2 | 11.20 | 4.87 | 3.27 |
| SnTe | 0.50 | 0.01 | 0.01 | 275044.3 | 21.77 | 12.57 | 8.89 |
| CoO | 0.73 | 0.07 | 0.17 | 260792.6 | 16.69 | 5.39 | 3.52 |
| LaSb | 0.80 | 0.02 | 0.04 | 245626.9 | 31.00 | 10.75 | 6.80 |
| Cu₃SbSe₄ | 0.31 | 0.40 | 0.02 | 242635.0 | 10.81 | 7.25 | 5.36 |
| CeN | 0.70 | 0.23 | 0.01 | 229900.6 | 39.03 | 14.75 | 9.76 |

Herein, the bulk semiconductor crystal has a particle radius of greater than or equal to about 1 μm.

Based on Table 1 and the following Equation 1, the particle radius (R) of the light absorbing material may be selected to have a desired energy bandgap.

$$E = {E}_{g} + \frac{{π}^{2} {h}^{2}}{2 {R}^{2}} ( \frac{1}{{m}_{e}^{*}} + \frac{1}{{m}_{h}^{*}} ) \qquad [ Equation 1 ]$$

In Equation 1, E denotes energy bandgap of a semiconductor nanocrystal, Eg denotes energy bandgap of a bulk semiconductor crystal, R denotes a particle radius, and mₑ* and mₕ* denote effective mass of the semiconductor nanocrystal.

The light absorbing material may be synthesized in various methods, for example, a solution-phase synthesis method.

For example, when the solution-phase synthesis method is used to synthesize SnTe among the aforementioned light absorbing materials, the SnTe may be raised by supplying oleyl amine with bis[bis(trimethylsilyl)amino]tin(II) as a Sn source and trioctylphosphine telluride as a tellurium (Te) source. The light absorbing material may grow into various particle sizes depending on reaction conditions, for example, injection temperature of the sources, growth temperature, and/or concentration of the oleyl amine. The injection and growth temperatures of the sources may vary depending on other reaction conditions, but, for example, range from about 90° C. to 150° C.

Accordingly, the reaction conditions may be controlled, so that the light absorbing material may have an adjusted particle size realizing a desired energy bandgap and absorption wavelength range.

Hereinafter, a solar cell including the light absorbing material according to example embodiments is described referring to drawings.

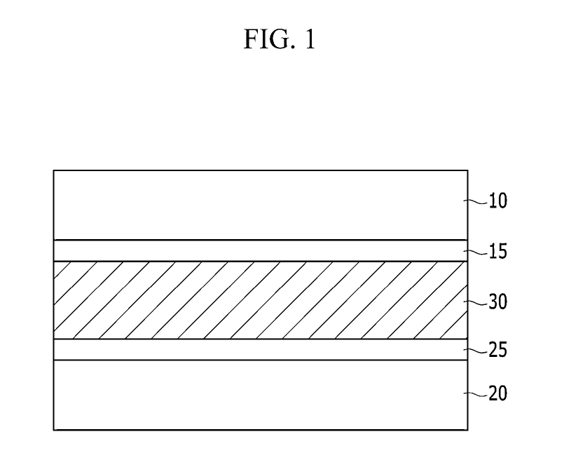

FIG. 1 is a cross-sectional view showing a solar cell according to example embodiments. Referring to FIG. 1, a solar cell includes a first electrode 10 and a second electrode 20, and a photoactive layer 30 positioned between the first electrode 10 and the second electrode 20.

A substrate (not shown) may be positioned at the first electrode 10 or the second electrode 20, and may be made of a light-transmitting material. The light-transmitting material may include, for example, an inorganic material (e.g., glass), or an organic material (e.g., polycarbonate, polymethylmethacrylate, polyethylene terephthalate, polyethylene naphthalate, polyamide, polyethersulfone, or a combination thereof).

One of the first electrode 10 and the second electrode 20 is an anode and the other is a cathode. At least one of the first electrode 10 and second electrode 20 may be a light-transmitting electrode, and light may enter toward the light-transmitting electrode. The light-transmitting electrode may be made of, for example, a conductive oxide (e.g., indium tin oxide (ITO)), indium doped zinc oxide (IZO), tin oxide (SnO₂), aluminum-doped zinc oxide (AZO), and/or gallium-doped zinc oxide (GZO), or a transparent conductor of a conductive carbon composite (e.g., carbon nanotubes (CNT) or graphenes). At least one of the first electrode 10 and the second electrode 20 may be an opaque electrode, which may be made of an opaque conductor, for example, aluminum (Al), silver (Ag), gold (Au), and/or lithium (Li).

The photoactive layer 30 includes a light absorbing material being capable of absorbing light of a predetermined or given wavelength range, and the light absorbing material may have an energy bandgap of greater than or equal to about 0.8 eV and an absorption coefficient of greater than about 2.1×10⁵ cm⁻¹ at about 0.8 eV.

The light absorbing material may be, for example, a binary compound or a ternary compound synthesized by combining elements of Groups I to VI, for example, a compound of Groups IA and VA, a compound of Groups VIIB and IVA, a compound of Groups VIII and VA, a compound of Group VIII and VIA, a compound of Groups IIIA and VIA, a compound of Groups IVB and VIA, a lanthanide compound, or a combination thereof.

The light absorbing material may be a semiconductor nanocrystal having a particle radius of several nanometers to hundreds of nanometers, for example, a quantum dot. The light absorbing material may have an energy bandgap that is regulated depending on a material and its size. For example, if the light absorbing material has a smaller particle radius, the light absorbing material has a larger energy bandgap. If the light absorbing material has a larger particle radius, the light absorbing material has a smaller energy bandgap.

The light absorbing material may include, for example, a bulk semiconductor crystal having an energy bandgap of less than 0.8 eV, and having a particle radius of about 2 nm to about 500 nm, while realizing an energy bandgap of greater than or equal to about 0.8 eV.

The light absorbing material may include at least one semiconductor nanocrystal selected from, for example, RhSb₃, CeN, SnTe, LaSb, CoSb₃, ZnSnSb₂, CsBi₂, Cu₃SbSe₄, MnSi, Cu₂SnSe₃, Cu₃SbS₄, SmSb, CoO, Li₃P, TISe, PrSb, and PtS.

The light absorbing material may have a particle radius of, for example, about 2 nm to about 500 nm, and may be selected so that desired energy bandgaps and an absorption wavelength range may be obtained within the above range of the particle radius. For example, the photoactive layer 30 includes a light absorbing material having a particle radius showing an energy bandgap of about 1.3 eV, which may accomplish efficiency near theoretical efficiency of a single cell. Accordingly, the efficiency of a solar cell may be improved by increasing the absorption coefficient of the photoactive layer 30.

On the other hand, the photoactive layer 30 may be thinner due to its higher absorption coefficient. Accordingly, the photoactive layer 30 may realize a relatively thin solar cell, because an about 1 nm to 100 nm-thick photoactive layer absorbs the same amount of light as a conventional solar cell.

First and second auxiliary layers 15 and 25 may be positioned between the first electrode 10 and the photoactive layer 30 and between the second electrode 20 and the photoactive layer 30, respectively. The first and second auxiliary layers 15 and 25 may increase charge mobility between the first electrode 10 and the photoactive layer 30 and between the second electrode 20 and the photoactive layer 30. The first and second auxiliary layers 15 and 25 may be at least one selected from, for example, an electron injection layer (EIL), an electron transport layer, a hole injection layer (HIL), a hole transport layer, and a hole blocking layer, but are not limited thereto. One or both of the first and second auxiliary layers 15 and 25 may be omitted.

The photoactive layer 30 may have a tandem structure where at least two thereof are stacked.

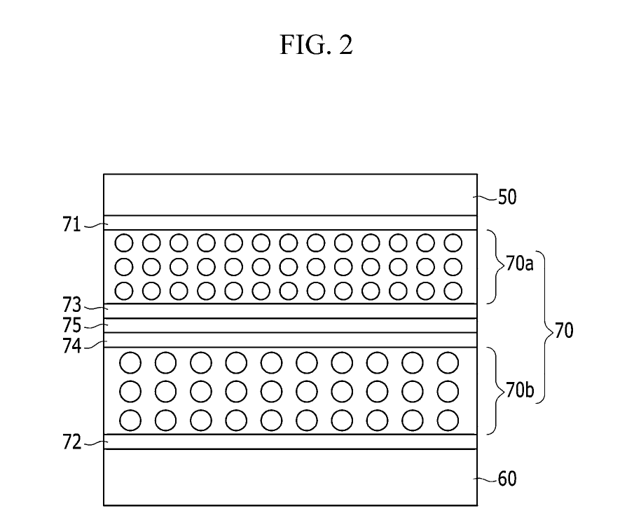

A solar cell having a tandem structure is described referring to FIG. 2.

FIG. 2 is a cross-sectional view of a solar cell according to example embodiments. Referring to FIG. 2, a solar cell includes a first electrode 50 and a second electrode 60 facing each other, and a photoactive layer 70 positioned between the first electrode 50 and the second electrode 60 like the above-described embodiment. The photoactive layer 70 may include a light absorbing material having an energy bandgap of greater than or equal to about 0.8 eV and an absorption coefficient of greater than about 2.1×10⁵ cm⁻¹ at about 0.8 eV, and may include at least one semiconductor nanocrystal selected from, for example, RhSb₃, CeN, SnTe, LaSb, CoSb₃, ZnSnSb₂, CsBi₂, Cu₃SbSe₄, MnSi, Cu₂SnSe₃, Cu₃SbS₄, SmSb, CoO, Li₃P, TISe, PrSb, and PtS.

However, the photoactive layer 70 includes a first photoactive layer 70a and a second photoactive layer 70b including the light absorbing materials having different particle sizes from each other, unlike the above-described embodiment. The first photoactive layer 70a may include a light absorbing material having a first particle radius, and the second photoactive layer 70b may include the light absorbing material having a larger second particle radius than the first particle radius, wherein the first photoactive layer 70a may absorb light of a shorter wavelength range than the second photoactive layer 70b. For example, the first photoactive layer 70a may include a light absorbing material having a particle radius of about 3 nm to about 13 nm, the second photoactive layer 70b may include a light absorbing material having a particle radius of about 4 nm to about 28 nm, so the first photoactive layer 70a may absorb light of less than or equal to about 826 nm, and the second photoactive layer 70b may absorb light of about 827 nm to about 1771 nm.

An interconnecting layer 75 may be interposed between the first photoactive layer 70a and the second photoactive layer 70b.

The interconnecting layer 75 may be a recombination center of charges of the first photoactive layer 70a and charges of the second photoactive layer 70b. The interconnecting layer 75 may include, for example a conductive polymer (e.g., PEDOT:PSS, a metal, a metal oxide, or a combination thereof), and may be a single layer or a multilayer. The metal oxide may be an oxide of nickel (Ni), ruthenium (Ru), tungsten (W), molybdenum (Mo), vanadium (V), iridium (Ir), titanium (Ti), zinc (Zn), or a combination thereof, but is not limited thereto.

Each of first through fourth auxiliary layers 71, 72, 73, and 74 may be positioned between the first electrode 50 and the first photoactive layer 70a, between the second electrode 60 and the second photoactive layer 70b, between the first photoactive layer 70a and the interconnecting layer 75, and between the second photoactive layer 70b and the interconnecting layer 75. The first through fourth auxiliary layers 71, 72, 73, and 74 may increase charge mobility between the first electrode 50 and the first photoactive layer 70a, between the second electrode 60 and the second photoactive layer 70b, between the first photoactive layer 70a and the interconnecting layer 75, and between the second photoactive layer 70b and the interconnecting layer 75. The first through fourth auxiliary layers 71, 72, 73, and 74 may be at least one selected from, for example, an electron injection layer (EIL), an electron transport layer, a hole injection layer (HIL), a hole transport layer, and a hole blocking layer, but are not limited thereto. At least one of the first through fourth auxiliary layers 71, 72, 73, and 74 may be omitted, or all of them may be omitted.

According to example embodiments, the solar cell includes two photoactive layers absorbing light having different wavelength ranges, and thus may have an enlarged light-absorption wavelength range and an increased light absorption rate. For example, when the first electrode 50 is a solar light-receiving side, the first photoactive layer 70a may absorb light of a shorter wavelength range, while the second photoactive layer 70b may absorb light of a longer wavelength range.

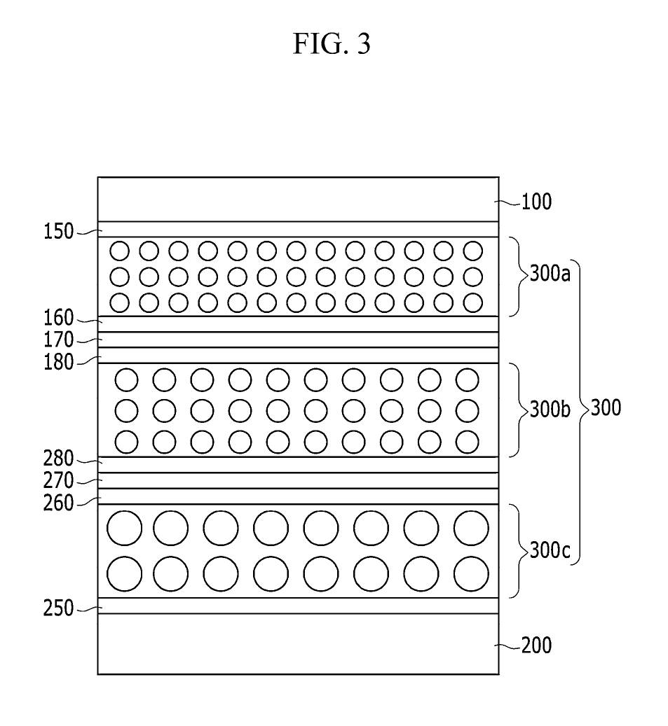

A solar cell having a tandem structure as another example is described referring to FIG. 3.

FIG. 3 is a cross-sectional view of a solar cell according to example embodiments. Referring to FIG. 3, the solar cell includes a first electrode 100 and a second electrode 200 facing each other, and a photoactive layer 300 positioned between the first electrode 100 and the second electrode 200. The photoactive layer 300 may include a light absorbing material having an energy bandgap of greater than or equal to about 0.8 eV and an absorption coefficient of greater than about 2.1×10⁵ cm⁻¹ at about 0.8 eV, and may include at least one semiconductor nanocrystal selected from, for example, RhSb₃, CeN, SnTe, LaSb, CoSb₃, ZnSnSb₂, CsBi₂, Cu₃SbSe₄, MnSi, Cu₂SnSe₃, Cu₃SbS₄, SmSb, CoO, Li₃P, TISe, PrSb, and PtS

However, the photoactive layer 300 includes a first photoactive layer 300a, a second photoactive layer 300b, and a third photoactive layer 300c including the light absorbing materials having different particle sizes from each other. The first photoactive layer 300a may include a light absorbing material having a first particle radius, the second photoactive layer 300b may include a light absorbing material having a larger second particle radius than the first particle radius, and the third photoactive layer 300c may include a light absorbing material having a larger third particle radius than the second particle radius. Herein, the first particle radius, the second particle radius, and the third particle radius may be determined considering energy bandgaps and wavelength ranges of lights that are absorbed in the first photoactive layer 300a, the second photoactive layer 300b, and the third photoactive layer 300c, respectively.

For example, the first photoactive layer 300a may include a light absorbing material having a particle radius showing an energy bandgap of about 2.1 eV to about 2.5 eV, the second photoactive layer 300b may include a light absorbing material having a particle radius showing an energy bandgap of about 1.2 eV to about 1.6 eV, and the third photoactive layer 300c may include a light absorbing material having a particle radius showing an energy bandgap of about 0.8 eV to about 1.0 eV.

For example, the first photoactive layer 300a, the second photoactive layer 300b, and the third photoactive layer 300c may absorb light respectively having a first wavelength range, a second wavelength range, and a third wavelength range. The first wavelength range may be less than or equal to about 590 nm, the second wavelength range may be from about 591 nm to about 1033 nm, and the third wavelength range may be from about 1034 nm to about 2066 nm.

Considering the energy bandgap and absorption wavelength range, the first particle radius may range from about 2 nm to about 20 nm, the second particle radius may range from about 3 nm to about 50 nm, and the third particle radius may range from about 6 nm to about 300 nm, which may be changed depending on the type of light absorbing materials.

Referring to Table 1, when the photoactive layer 300 includes, for example, a RhSb₃ semiconductor crystal, the first, second, and third photoactive layers 300a, 300b, and 300c respectively include a RhSb₃ semiconductor nanocrystal having an average particle radius of about 9.65 nm, about 15.26 nm, and about 255.00 nm, and thus, may be controlled to each have an energy bandgap of about 2.3 eV, about 1.4 eV, and about 0.8 eV. Accordingly, the first, second, and third photoactive layers 300a, 300b, and 300c respectively absorb light having a first wavelength range of less than or equal to about 590 nm, a second wavelength range from about 591 nm to 1033 nm, and a third wavelength range from about 1034 nm to 2066 nm, and thus may accomplish a relatively high absorption coefficient of greater than or equal to about 8.6×10⁵ cm⁻¹.

On the other hand, the photoactive layer 300 may be formed to be thinner by increasing the absorption coefficient thereof. Accordingly, the photoactive layer 300 has a thickness of about 1 nm to 100 nm but absorbs the same amount of light as a conventional solar cell, and thus may realize a thinner solar cell.

First and second interconnecting layers 170 and 270 may be positioned between the first photoactive layer 300a and the second photoactive layer 300b and between the second photoactive layer 300b and the third photoactive layer 300c, respectively. The first interconnecting layer 170 may be a recombination center of charges of the first photoactive layer 300a and charges of the second photoactive layer 300b, while the second interconnecting layer 270 may be a recombination center of charges of the first photoactive layer 300b and charges of the second photoactive layer 300c. The first and second interconnecting layers 170 and 270 may include, for example, a conductive polymer (e.g., PEDOT:PSS, a metal, a metal oxide, or a combination thereof), and may be a single layer or a multilayer. The metal oxide may be an oxide of nickel (Ni), ruthenium (Ru), tungsten (W), molybdenum (Mo), vanadium (V), iridium (Ir), titanium (Ti), zinc (Zn), or a combination thereof, but is not limited thereto.

Each of first through sixth auxiliary layers 150, 160, 180, 280, 260, and 250 may be positioned between the first electrode 100 and the first photoactive layer 300a, between the first photoactive layer 300a and the interconnecting layer 170, between the interconnecting layer 170 and the second photoactive layer 300b, between the second photoactive layer 300b and the interconnecting layer 270, between the interconnecting layer 270 and the third photoactive layer 300c, and between the third photoactive layer 300c and the second electrode 200. The first through sixth auxiliary layers 150, 160, 180, 280, 260, and 250 may increase charge mobility between the first electrode 100 and the first photoactive layer 300a, between the first photoactive layer 300a and the interconnecting layer 170, between the interconnecting layer 170 and the second photoactive layer 300b, between the second photoactive layer 300b and the interconnecting layer 270, between the interconnecting layer 270 and the third photoactive layer 300c, and between the third photoactive layer 300c and the second electrode 200. The first through sixth auxiliary layers 150, 160, 180, 280, 260, and 250 may be at least one selected from, for example, an electron injection layer (EIL), an electron transport layer, a hole injection layer (HIL), a hole transport layer, and a hole blocking layer, but are not limited thereto. At least one of the first through sixth auxiliary layers 150, 160, 180, 280, 260, and 250 may be omitted or all of them may be omitted.

According to example embodiments, the solar cell may include three photoactive layers absorbing light having different wavelength ranges, and thus may have an enlarged wavelength range and an increased light absorption rate. For example, when the first electrode 100 is a light-receiving side, the first photoactive layer 300a absorbs light having a first wavelength range, the second photoactive layer 300b absorbs light having a second wavelength range longer than the first wavelength range, and the third photoactive layer 300c absorbs light having a third wavelength range longer than the first and second wavelength ranges.

Hereinafter, this disclosure is illustrated in more detail with reference to examples and comparative examples. However, these are only examples, and this disclosure is not limited thereto.

### Synthesis of SnTe Nanocrystal

2.325 mg of tellurium (Te) powder is added to 25 ml of trioctylphosphine and dissolved therein at 260° C. for 3 hours, preparing a tellurium (Te) solution. Next, 14 ml of vacuum-dried oleyl amine is put in a 100 ml flask and deaerated and vacuum-dried at 100° C. for 1 hour. Then, 1 ml of the tellurium solution is provided in the flask, preparing a tellurium source.

In addition, 0.16 ml (0.4 mmol) of bis[bis(trimethylsilyl)amino]tin(II) is added to 6 ml of 1-octadecene, and then dissolved therein at 90° C. for 1 hour, preparing a tin (Sn) source. The tellurium source is heated up to 180° C., and 6.16 ml of the tin source is added thereto. The mixture is vigorously agitated and cooled down to about 120 to 150° C., and one minute and thirty seconds later, rapidly cooled down again, completing the reaction.

Next, 3 ml of oleic acid is added to the reaction product, and a mixed solvent prepared by mixing chloroform/acetone in a ratio of 1:1 is provided therewith. The mixture is centrifuged to separate a product therein. The separated product is dispersed into chloroform, and then precipitated with acetone and purified, obtaining SnTe particles. The SnTe particles are dissolved in a non-polar solvent, preparing a stable colloid solution.

### Preparation of SnTe Nanocrystal Superlattice

The colloid solution is put in a glass vial, and a substrate is positioned therein. The glass vial is slanted 60-70° in a low pressure chamber. Then, a solvent is removed from the colloid solution at about 50° C. under a reduced pressure, forming an ordered superlattice.

### Identification of SnTe Nanocrystal Superlattice

The SnTe nanocrystal according to the synthesis example is identified using a transmission electron microscope (TEM).

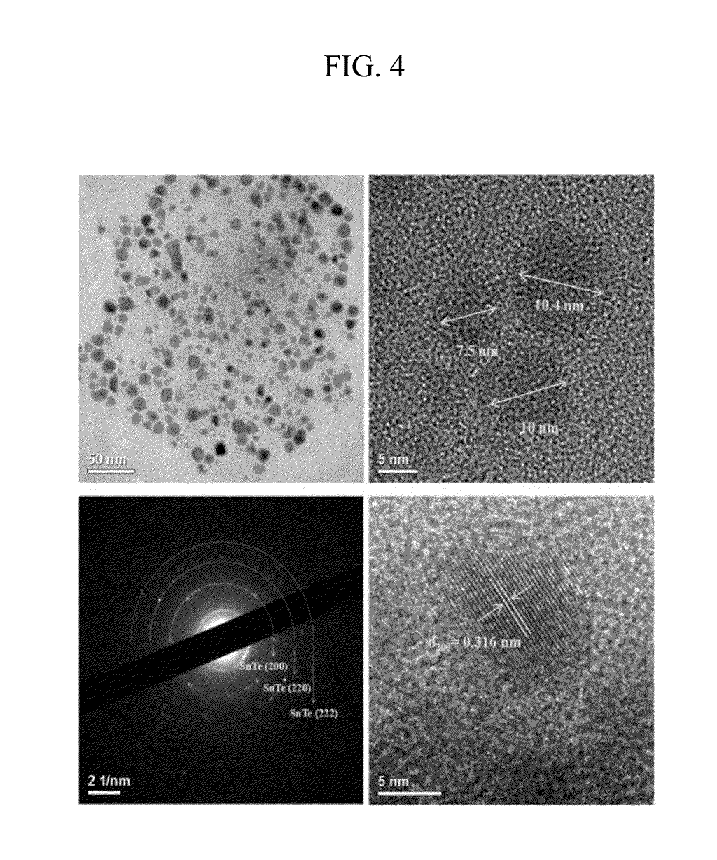

FIG. 4 is a transmission electron microscope (TEM) photograph showing the SnTe nanocrystal according to the synthesis example.

Referring to FIG. 4, the SnTe nanocrystal according to the synthesis example has sizes of about 7.5 nm, about 10 nm and about 10.4 nm.

While this disclosure has been described in connection with what is presently considered to be practical example embodiments, it is to be understood that the inventive concepts are not limited to the disclosed embodiments, but, on the contrary, is intended to cover various modifications and equivalent arrangements included within the spirit and scope of the appended claims.

What is claimed is:

1. A light absorbing material having an energy bandgap of greater than or equal to about 0.8 eV and an absorption coefficient of greater than about 2.1×10⁵ cm⁻¹ at about 0.8 eV.

2. The light absorbing material of claim 1, wherein the light absorbing material is at least one material selected from RhSb₃, CeN, SnTe, LaSb, CoSb₃, ZnSnSb₂, CsBi₂, Cu₃SbSe₄, MnSi, Cu₂SnSe₃, Cu₃SbS₄, SmSb, CoO, Li₃P, TISe, PrSb, and PtS.

3. The light absorbing material of claim 1, wherein
the light absorbing material is a semiconductor crystal having a particle radius of about 2 nm to about 500 nm, and
the energy bandgap of the light absorbing material varies depending on the particle radius.

4. A solar cell, comprising:
a first electrode and a second electrode facing each other; and
at least one photoactive layer between the first electrode and the second electrode, the at least one photoactive layer including a light absorbing material having an energy bandgap of greater than or equal to about 0.8 eV and an absorption coefficient of greater than about 2.1×10⁵ cm⁻¹ at about 0.8 eV.

5. The solar cell of claim 4, wherein the light absorbing material is at least one material selected from RhSb₃, CeN, SnTe, LaSb, CoSb₃, ZnSnSb₂, CsBi₂, Cu₃SbSe₄, MnSi, Cu₂SnSe₃, Cu₃SbS₄, SmSb, CoO, Li₃P, TISe, PrSb, and PtS.

6. The solar cell of claim 4, wherein the light absorbing material is a semiconductor crystal having a particle radius of about 2 nm to about 500 nm.

7. The solar cell of claim 4, further comprising:
an auxiliary layer between at least one of the first electrode and the at least one photoactive layer, and the second electrode and the at least one photoactive layer.

8. The solar cell of claim 4, wherein the at least one photoactive layer has a tandem structure including at least two stacked photoactive layers.

9. The solar cell of claim 8, wherein the at least one photoactive layer includes a first photoactive layer and a second photoactive layer including light absorbing materials having different particle radii from each other.

10. The solar cell of claim 9, wherein
the first photoactive layer includes a light absorbing material having a first particle radius,
the second photoactive layer includes the light absorbing material having a second particle radius, the second particle radius larger than the first particle radius, and
the first photoactive layer absorbs light having a shorter wavelength range than the second photoactive layer.

11. The solar cell of claim 9, further comprising:
an interconnecting layer between the first photoactive layer and the second photoactive layer.

12. The solar cell of claim 8, wherein the at least one photoactive layer includes a first photoactive layer, a second photoactive layer, and a third photoactive layer including light absorbing materials having different particle radii from each other.

13. The solar cell of claim 12, wherein
the first photoactive layer includes a light absorbing material having a particle radius showing an energy bandgap of about 2.1 eV to about 2.5 eV,
the second photoactive layer includes a light absorbing material having a particle radius showing an energy bandgap of about 1.2 eV to about 1.6 eV, and
the third photoactive layer includes a light absorbing material having a particle radius showing an energy bandgap of about 0.8 eV to about 1.0 eV.

14. The solar cell of claim 12, wherein
the first photoactive layer includes a light absorbing material having a first particle radius,
the second photoactive layer includes a light absorbing material having a second particle radius, the second particle radius larger than the first particle radius,
the third photoactive layer includes a light absorbing material having a third particle radius, the third particle radius larger than the second particle radius, and
the first photoactive layer, the second photoactive layer, and the third photoactive layer absorb light having a first wavelength range, a second wavelength range longer than the first wavelength range, and a third wavelength range longer than the first and second wavelength ranges, respectively.

15. The solar cell of claim 14, wherein the first particle radius ranges from about 2 nm to about 20 nm, the second particle radius ranges from about 3 nm to about 50 nm, and the third particle radius ranges from about 6 nm to about 300 nm.

16. The solar cell of claim 14, wherein the first wavelength range is less than or equal to about 590 nm, the second wavelength range is from about 591 nm to about 1033 nm, and the third wavelength range is from about 1034 nm to about 2066 nm.

17. The solar cell of claim 12, further comprising:
at least one interconnecting layer between the first photoactive layer and the second photoactive layer, and between the second photoactive layer and the third photoactive layer.

18. A solar cell comprising:
a first electrode and a second electrode facing each other; and
at least one photoactive layer between the first electrode and the second electrode, the at least one photoactive layer including a light absorbing material having a particle radius of about 2 nm to 500 nm,
wherein the light absorbing material is at least one material selected from RhSb₃, CeN, SnTe, LaSb, CoSb₃, ZnSnSb₂, CsBi₂, Cu₃SbSe₄, MnSi, Cu₂SnSe₃, Cu₃SbS₄, SmSb, CoO, Li₃P, TISe, PrSb, and PtS.

19. The solar cell of claim 18, wherein the at least one photoactive layer includes a first photoactive layer, a second photoactive layer, and a third photoactive layer including light absorbing materials having different particle radii from each other.

20. The solar cell of claim 19, wherein
the first photoactive layer includes a light absorbing material having a particle radius of about 2 nm to about 20 nm,
the second photoactive layer includes a light absorbing material having a particle radius of about 3 nm to about 50 nm, and
the third photoactive layer includes a light absorbing material having a particle radius of about 6 nm to about 300 nm.
